(19) United States
(12) Patent Application Publication
(10) Pub. No.: US 2006/0002571 A1
(43) Pub. Date: Jan. 5, 2006

(54) Self-adjusted car stereo system

(75) Inventors: Lane Thomas Holloway, Pflugerville, TX (US); Walid M. Kobrosly, Round Rock, TX (US); Marques Benjamin Quiller, Pflugerville, TX (US)

Correspondence Address: IBM CORPORATION (VE);C/O VOLEL EMILE, P. O. BOX 202170, AUSTIN, TX, 78720-2170, US

(73) Assignee: International Business Machines Corporation, Armonk, NY (US)

(21) Appl. No.: 10/880,717

(22) Filed: Jun. 30, 2004

(51) Int. Cl. H03G 3/00; H04B 1/00

(52) U.S. Cl. 381/104; 381/86

(57) ABSTRACT

A self-adjusted car stereo system is provided. The system includes means for allowing a user to select an ideal listening location. After the ideal listening location has been selected, the system will determine whether sound from each speaker reaches the ideal listening location at the same volume level. If not, the system will automatically adjust the volume of the speakers to ensure that it is indeed so.

### BACKGROUND OF THE INVENTION

1. Technical Field

The present invention is directed to stereo systems. More specifically, the present invention is directed to a self-adjusted car stereo system.

2. Description of Related Art

A stereo system has two independent channels, one left and one right. The two channels give depth to a reproduced audio sound. For example, in a listening area there usually is a “sweet spot” at which audio sound is optimized. If sound from an instrument is produced in both channels at the same magnitude, the sound may appear to originate directly between the two speakers from which the sound is being reproduced. If the sound from the instrument is produced only in the left channel, it will seem to originate from the left. Or, if the sound is slightly louder in the right channel, it will seem to originate a bit off center and slightly toward the right.

The listening area in a car is the car cabin. As is well known, a car cabin is a relatively small enclosure that includes different materials (i.e., cloth, leather, plastic, metal, carpet etc.). Consequently, it may be difficult to find the sweet spot within a car cabin. Nonetheless, car manufacturers have generally designed car stereo systems with an ideal listening location (i.e., the center of the cabin or a location where sound emanating from all the speakers will reach a listener at the same volume level or magnitude). If a user wants to shift the ideal listening location in the cabin to a different location, the user has to adjust the magnitude of the audio signals from one or both channels using one or all of the balance, fader (if there are rear speakers) and equalizer (if one is available) controls of the car stereo system. Particularly, a user who wants to have his/her seating location be the ideal listening location has to adjust the controls to ensure that sound reproduced in speakers that are at different distances away from the user reach the user as if the user was at the center of the car cabin.

One problem, however, that arises is that each time a person enters or leaves the car, the magnitude of the audio signals may have to be re-adjusted to ensure that the ideal listening location remains constant. This is because audio sound emanating from the speakers may be deflected or bounced off occupants in the car. Consequently, when a passenger is in the car, the passenger may deflect sound from the speakers away from the ideal listening location. This, in turn, may shift the ideal listening location away from where it previously was. By contrast, when the passenger leaves the car, sound that may have been deflected by the passenger may no longer be deflected. Again, this may shift the ideal listening location away from where it previously was. Thus, to ensure that the ideal listening location remains constant, the magnitude of the audio signals may have to accordingly be adjusted each time a person enters or leaves the car. Note that adjustments and re-adjustment may also be made to decrease/increase the volume of the sound from the speaker closest to an occupant in the car if the volume of that speaker was the loudest/softest etc.).

In any case, this adjustment is ordinarily made manually. This can be quite a time consuming and frustrating endeavor as the user may have to continuously adjust the controls whenever a person enters or exits the car.

Thus, what is needed is a self-adjusted car stereo system.

### SUMMARY OF THE INVENTION

The present invention provides a self-adjusted car stereo system. The system includes means for allowing a user to select an ideal listening location. After the ideal listening location has been selected, the system will determine whether sound from each speaker reaches the ideal listening location at the same volume level. If not, the system will automatically adjust the volume of the speakers to ensure that it is indeed so.

In one embodiment, the system automatically adjusts the volume speakers by determining which seats in the car are occupied. Based on preset volume levels associated with occupied seats, the system will automatically adjust the volume level of the speakers.

In another embodiment, the system uses sound detectors or sensors at possible ideal listening locations to automatically adjust the volume of the speakers. Particularly, after an ideal listening location has been selected, the system emits an inaudible sound from each of the speakers in a round robin fashion. A sensor at the ideal listening location will capture the sound. The system will then determine if the captured sound from each of the speakers is at the same volume level. If not, the system will adjust the volume level of the speakers until sound from each of the speakers reaches the ideal listening location at the same volume level.

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1 depicts a schematic block diagram of an on-board computer (OBC) of a car.

FIG. 2 depicts a selected ideal listening location in a car.

FIG. 3 is a flow chart of a process that may be used by the invention.

FIG. 4 is a flowchart of an alternative process that may be used.

### DETAILED DESCRIPTION OF THE PREFERRED EMBODIMENT

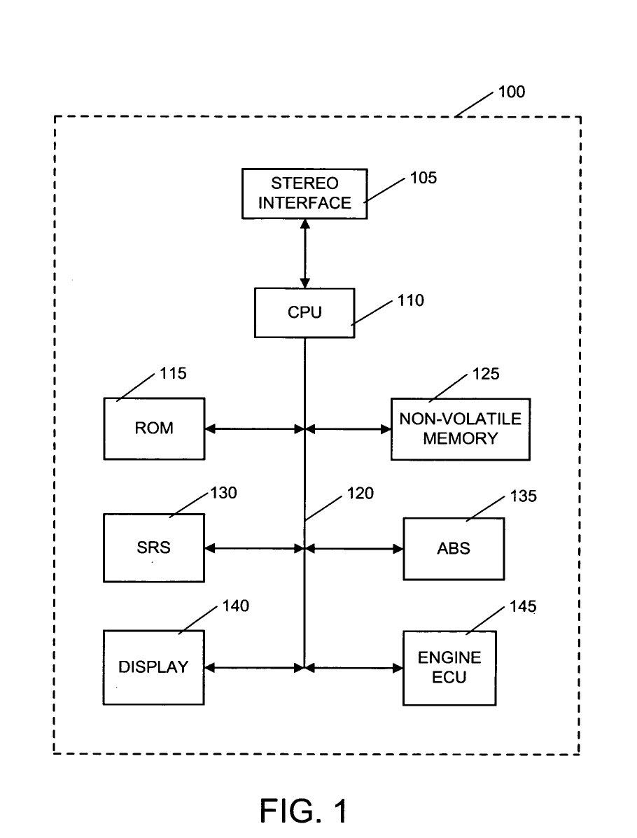

Modern vehicles are typically equipped with an on-board computer system (OBC). The OBC is used to perform diagnostic functions as well as to control the vehicles. FIG. 1 depicts a schematic block diagram of an exemplary OBC 100 of a vehicle. The OBC 100 includes a CPU 110 that is connected to a non-volatile memory 125, an anti-lock braking system (ABS) 135, an engine electronic control unit (ECU) 145, ROM 115, supplemental restraint system (SRS) 130 and dash display 140 through bus 120.

The non-volatile memory 125 may be used to store data such as odometer readings, total mileage of the vehicle, the vehicle identification number (VIN), etc. The ROM 115 may be used to store a software package that controls the CPU 110. For example, the CPU 110, under the control of a software program, may display battery voltage, speedometer readings, turn on and/or off all dash display lights etc.

The ABS 135 may have its own co-processor or use the CPU 110. In either case, when a driver applies the brake in a panic, the ABS 135 may modulate the breaking force that is actually applied to the wheels. Furthermore, if a wheel is slipping, the ABS 135 may slow the wheel down and/or shift the driving force to a non-slipping wheel etc.

The engine ECU 145 controls the engine, self-diagnoses abnormalities relating to the exhaust emission of the engine and transmits the information to the CPU 110 for storage into the non-volatile memory 125 and/or for display on display 140. For example, a problem with the engine may turn on a “check engine” light on the dashboard. The problem may be stored in memory to be read out by a mechanic.

The SRS 130 includes front airbags, side impact airbags, rear airbags, safety belts etc. In some modern vehicles, the SRS 130 may include sensors to determine whether there are occupants in the seats, the weight of the occupants as well as whether seat belts are fastened. With this information, SRS 130 determines whether any one of the airbags is to be deployed and at what force etc. in case of an accident.

The sensors that determine the weight and location of the occupants of SRS 130 may also be used by the present invention. The location sensors may be used to determine the seats that are occupied whereas the weight sensors may be used to ensure that there are indeed occupants instead of packages in those seats. Thus, if a user indicates through an option on the dash or in the stereo system itself that the place where the driver's seat is located should be the ideal listening location, controls of the stereo system may then be automatically adjusted to ensure that it remains the ideal listening location regardless of the number of occupants in the car.

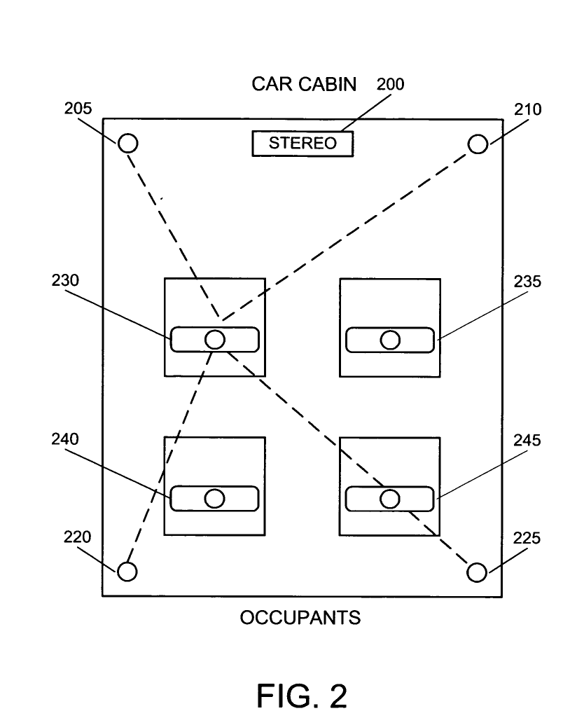

FIG. 2 depicts a car cabin. The car cabin is occupied by a plurality of occupants (e.g., operator 230, front passenger 235 and rear passengers 240 and 245). The car has a stereo system 200 and four speakers (i.e., speakers 205, 210, 220 and 225). In this configuration, the driver's seat location has been chosen as the ideal listening location. Consequently, the volume of front speaker 210 may be a bit higher than that of front speaker 205 since it is farther away from the operator 230. This can be adjusted by using the balance control of the stereo system. Likewise, the volume of rear speaker 225 may be higher than that of rear speaker 220 since it is at a greater distance away from the operator 230. Again, this may be adjusted by the balance control of the stereo system 200. Rear speakers are generally farther away from the front occupants of a car than the front speakers are. Consequently, the rear speakers may have a higher volume than the front speakers. This may be adjusted by the fader control of the stereo system 200.

In this example, rear passenger 245 is in the direct path of the sound emanating from rear speaker 225 to operator 230. Thus, the direct sound from rear speaker 225 may bounce off rear passenger 245. Nonetheless, sound from speaker 225 will reach operator 230. The sound from speaker 225 that reaches operator 230 may be stray sound that has been reflected off the ceiling, floor, doors, windows, etc. of the car; and hence, may be attenuated. Thus, the volume of rear speaker 225 may be further increased to overcome this attenuation.

When rear passenger 225 exits the car, the volume of rear speaker 225 may be lowered since the direct sound will reach operator 230. This adjustment may be done automatically. Specifically, when the location and weight sensors in the seat that was occupied by rear passenger 245 indicate that the seat is no longer occupied, the system may automatically readjust itself to ensure that sound emanating from each speaker reaches the driver with the same magnitude.

Obviously, the ideal listening location may be any area in the car cabin. For example, any location where there is a passenger may be chosen as the ideal listening location. Further, the front of the cabin (e.g., if only the front seats are occupied) as well as the rear of the cabin (e.g., if only the rear passengers are interested in a particular music) may be chosen as the ideal listening location. In the case where the front seats are chosen as the ideal listening location, the fader control of the stereo system may be adjusted to allow sound from the rear and the front speakers to reach the passengers in the front seats at the same volume. Likewise, when the rear seats are chosen as the ideal listening location, the sound may be adjusted to have sound from the rear and the front speakers reach passengers in the rear seats at the same volume.

Further, in certain instances the center of the cabin, which may be the default option, may be chosen as the ideal listening location. For example, when the car is fully loaded, that option may be chosen. This will ensure that sound from any one of the speakers will not reach any of the occupants at a disproportionately high volume since sound coming from all the speakers will be at the same volume.

In the description above, weight and location sensors in the seats were used in implementing the invention. However, the invention is not thus limited. For example, a sound magnitude sensor or a set of sound magnitude sensors in headrests of the car may instead be used to implement the invention. In the case where a set of sound magnitude sensors is used, the sensors may be strategically placed at the location where ears of a person may be located and may be used to determine whether sound from each speaker will reach the person (e.g., driver, front passenger, right rear passenger, left rear passenger etc.) in the area that has been chosen as the ideal listening location at the same volume level. To do so, an inaudible sound may be emitted from each speaker in a round robin fashion. The level at which the sound reaches the sensor in the area that has been chosen as the ideal listening location may thus be adjusted until sound from each speaker reaches the sensor or sensors at the same volume level.

When the front seats are chosen as the ideal listening location, the fader control of the stereo system may be adjusted to allow sound from the rear and the front speakers to reach the sensors in the headrests of the front seats at the same volume. Likewise, when the rear seats are chosen as the ideal listening location, the sound from the rear speakers and or the front speakers may be adjusted such that sound from the rear and the front speakers reach the sensors in the headrests of the rear seats at the same volume. In the case where center of the car is the ideal listening location, the volume of each speaker may be set at the same volume.

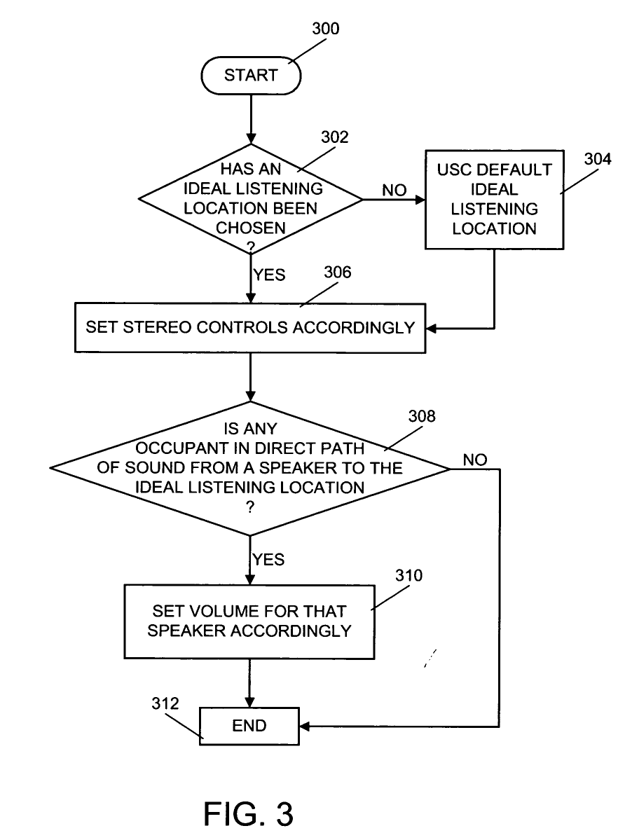

FIG. 3 is a flow chart of a process that may be used by the invention. The process may be stored in the vehicle's OBC and starts when the stereo is turned on (step 300). Then a check is made to determine whether an ideal location has been chosen (step 302). If not, a default location (i.e., the center of the car) is used as an ideal listening location. In this case, the volume of all the speakers is set at the same level or at a level that ensures that the center of the car is the ideal listening location Step 304). If an ideal listening location is chosen, the controls of the stereo system are set accordingly (step 306). Further, based on the placement of the speakers in the car as well as which seats are occupied and the chosen ideal listening location, the computer system can determine whether any occupant is in the direct path of sound coming from any one of the speakers to the ideal listening location (step 308). If so, the volume of that speaker may be adjusted. This adjustment may be a pre-set one (i.e., a preset amount of volume may be used) before the process ends. If no occupant is in the direct path of sound coming from any one of the speakers to the ideal listening location then the process ends (step (step 310 and 312).

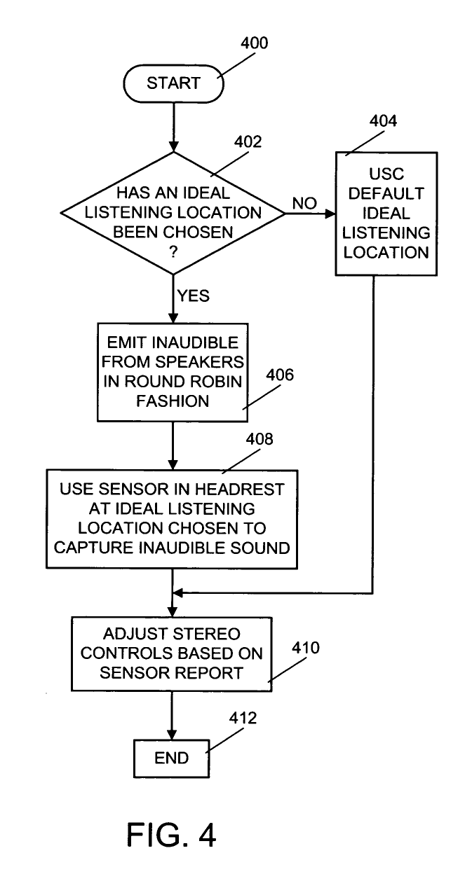

FIG. 4 is a flowchart of an alternative process that may be used. The process is based on whether or not sound sensors are used to ensure that sounds from all speakers are received at the ideal listening location at the same volume. Again the process starts when the stereo system is turned on (step 402). Then a check is made to determine whether an ideal listening location has been chosen (step 402). If not, a default location (i.e., the center of the car) is used as an ideal listening location. In this case, the volume of all the speakers is set at the same level or at a level that ensures that the center of the car is the ideal listening location before the process ends (steps 404, 410 and 412). If an ideal listening location is chosen, an inaudible sound may be emitted by each speaker in a round robin fashion. The inaudible sound may be captured by a sensor in a headrest at the ideal listening location and used to determine the volume level of each of the speakers (steps 406 and 408). Based on the volume of the inaudible sound from each of the speakers, the controls of the stereo system may be adjusted to ensure that the sensor receives sound from the speakers at the same volume level. Once this is done, the process may end (steps 406, 408, 410 and 412).

The description of the present invention has been presented for purposes of illustration and description, and is not intended to be exhaustive or limited to the invention in the form disclosed. Many modifications and variations will be apparent to those of ordinary skill in the art. Thus, the embodiment was chosen and described in order to best explain the principles of the invention, the practical application, and to enable others of ordinary skill in the art to understand the invention for various embodiments with various modifications as are suited to the particular use contemplated.

What is claimed is:

1. A method of automatically adjusting speaker volume of a car stereo system comprising the steps of:
selecting an area of the car that is to be an ideal listening location;
determining whether sound from each speaker of the stereo system is received at the selected ideal listening location at the same volume level; and
automatically adjusting, if the sound from each speaker is not received at the selected ideal listening location at the same volume, the speaker volume level of the stereo system such that sound from each speaker is received at the selected ideal listening location at the same volume level.

2. The method of claim 1 wherein sound sensors are used to determine whether the sound from each speaker is received at the selected ideal listening location at the same volume level.

3. The method of claim 2 wherein an inaudible sound is emitted from each speaker in a round robin fashion in order to determine whether the sound from each speaker is received at the selected ideal listening location at the same volume level.

4. The method of claim 1 wherein if an ideal listening location is not selected, a default ideal listening location is used.

5. The method of claim 1 wherein a predetermined sound volume is used for each speaker of the stereo system based on occupied seats.

6. A computer program product on a computer readable medium for automatically adjusting speaker volume of a car stereo system comprising:
code means for selecting an area of the car that is to be an ideal listening location;
code means for determining whether sound from each speaker of the stereo system is received at the selected ideal listening location at the same volume level; and
code means for automatically adjusting, if the sound from each speaker is not received at the selected ideal listening location at the same volume, the speaker volume level of the stereo system such that sound from each speaker is received at the selected ideal listening location at the same volume level.

7. The computer program product of claim 6 wherein sound sensors are used to determine whether the sound from each speaker is received at the selected ideal listening location at the same volume level.

8. The computer program product of claim 7 wherein an inaudible sound is emitted from each speaker in a round robin fashion in order to determine whether the sound from each speaker is received at the selected ideal listening location at the same volume level.

9. The computer program product of claim 6 wherein if an ideal listening location is not selected, a default ideal listening location is used.

10. The computer program product of claim 6 wherein a predetermined sound volume is used for each speaker of the stereo system based on occupied seats.

11. A self-adjusted car stereo system comprising:
means for enabling a user to select an area of the car that is to be an ideal listening location;
means for determining whether sound from each speaker of the stereo system is received at the selected ideal listening location at the same volume level; and
means for automatically adjusting, if the sound from each speaker is not received at the selected ideal listening location at the same volume, the speaker volume level of the stereo system such that sound from each speaker is received at the selected ideal listening location at the same volume level.

12. The self-adjusted car stereo system of claim 11 wherein sound sensors are used to determine whether the sound from each speaker is received at the selected ideal listening location at the same volume level.

13. The self-adjusted car stereo system of claim 12 wherein an inaudible sound is emitted from each speaker in a round robin fashion in order to determine whether the sound from each speaker is received at the selected ideal listening location at the same volume level.

14. The self-adjusted car stereo system of claim 11 wherein if an ideal listening location is not selected, a default ideal listening location is used.

15. The self-adjusted car stereo system of claim 11 wherein a predetermined sound volume is used for each speaker of the stereo system based on occupied seats.

16. A system for automatically adjusting speaker volume of a car stereo system comprising:
at least one storage device for storing code data; and
at least one processor for processing the code data to enable a user to select an area of the car that is to be an ideal listening location, to determine whether sound from each speaker of the stereo system is received at the selected ideal listening location at the same volume level and to automatically adjust, if the sound from each speaker is not received at the selected ideal listening location at the same volume, the speaker volume level of the stereo system such that sound from each speaker is received at the selected ideal listening location at the same volume level.

17. The system of claim 16 wherein sound sensors are used to determine whether the sound from each speaker is received at the selected ideal listening location at the same volume level.

18. The system of claim 17 wherein an inaudible sound is emitted from each speaker in a round robin fashion in order to determine whether the sound from each speaker is received at the selected ideal listening location at the same volume level.

19. The system of claim 15 wherein if an ideal listening location is not selected, a default ideal listening location is used.

20. The system of claim 16 wherein a predetermined sound volume is used for each speaker of the stereo system based on occupied seats.
